(19) United States
(12) Patent Application Publication
(10) Pub. No.: US 2021/0125793 A1
(43) Pub. Date: Apr. 29, 2021

(54) HIGH-TEMPERATURE, HIGH-PERFORMANCE CAPACITOR THIN FILM CONTINUOUS PRODUCTION DEVICE AND METHOD

(71) Applicant: Tsinghua University, Beijing (CN)

(72) Inventors: Li Qi, Beijing (CN); Jinliang He, Beijing (CN); Yao Zhou, Beijing (CN); Rong Zeng, Beijing (CN)

(21) Appl. No.: 17/253,204

(22) PCT Filed: Oct. 26, 2018
(86) PCT No.: PCT/CN2018/112187

§ 371 Date: Dec. 17, 2020

(30) Foreign Application Priority Data
Jul. 18, 2018 (CN) 2018107887832

(51) Int. Cl. H01G 13/02; H01G 4/32; H01G 4/33; C23C 16/54

(52) U.S. Cl. CPC H01G 13/02; C23C 16/545; H01G 4/33; H01G 4/32

(57) ABSTRACT

Disclosed are a high-temperature, high-performance capacitor thin film continuous production device and method. A thin film (3) to be processed is released by an unwinding roller (1), the position of the thin film to be processed is adjusted by an unwinding adjustment roller (2), such that the thin film is guaranteed to be located at the middle position of a discharge gap (12), and the thin film to be processed then passes through a plasma deposition area, the position of the processed thin film (7) is adjusted by a winding adjustment roller (4), and the processed thin film, after adjustment, is wound by a winding roller (6) after being drawn by a drawing roller (5), with the winding roller being an inflatable roller. The steady and controllable movement of the thin film in the deposition area is achieved. Large-scale continuous production, capable of matching the existing production speed of a polymer capacitor thin film, can be achieved using the device, wherein same has the advantages of flexible configuration, low environmental requirements, strong universality, a fast processing speed, low production costs and no pollution.

### FIELD OF THE INVENTION

The present invention relates to the technical field of film production, particularly to a kind of high-temperature, high-performance capacitor thin film continuous production device and method.

### BACKGROUND OF THE INVENTION

Dielectric capacitor has extremely fast charge and discharge rates (microsecond) and ultrahigh power density (MW/k), which is a kind of crucial power-type energy storage device, and plays a key role in high-power energy storage and pulse power systems, such as power grid frequency modulation, industrial energy saving, key medical equipment, industrial lasers, new energy automobiles and advanced electromagnetic weapons. Dielectric capacitors can be divided into organic polymer dielectric capacitors, inorganic dielectric capacitors, and electrolytic capacitors according to the dielectric materials used. Wherein, the capacitor using organic polymer as the dielectric material—the polymer thin film capacitor, has been widely used in electric automobiles, wind power, photovoltaic, lighting and railway locomotive and other industries based upon its characteristics of light weight, good processing performance, low production cost, high dielectric strength, good self-healing nature, simple integrated assembly process and no liquid medium, With the rapid development of industries such as smart grids and new energy, the demand for thin film capacitors increases progressively year by year.

Currently, the operating environment temperature of thin film capacitors used in many application fields is higher than room temperature, and the operating electric field is higher as well. The maximum operating temperature of most polymer dielectric materials is below 125° C. When the temperature gradually rises to close to the maximum operating temperature, the dielectric loss of polymer dielectric materials increases sharply. Especially under the action of a high electric field, the rise of temperature will cause the internal leakage current/conductivity of the polymer dielectric to show an exponential upward trend, and thus results in a sharp drop in the charge and discharge efficiency and energy storage density, which cannot satisfy the application requirements. Under the conditions of high temperature and strong electric field, the existing high temperature polymer dielectric materials cannot satisfy the application requirements, which is mainly because of two problems: one is the conductivity loss of polymer dielectric materials under high temperature conditions increases sharply with the increase of electric field, and thus results in significant decrease in energy storage density. The other is the large amount of conduction loss generated by the polymer dielectric material under the conditions of high temperature and strong electric field will also cause the dielectric material to even fail to operate continuously and stably in the environment far below its design temperature, which is caused by the phenomenon of thermal runaway of the thin film capacitor. How to effectively suppress the leakage current of capacitor thin films under the conditions of high temperature and high electric field has become a difficult problem in the design and preparation of high-performance capacitor thin films.

There are two technical approaches mainly used to increase the operating temperature of the capacitor thin film in the field of polymer capacitor thin film. One is to increase the glass transition temperature of the polymer capacitor thin film material, and thus increases its operating temperature. However, such technical method only improves the operating temperature of the capacitor thin film by improving the thermal performance of the capacitor thin film, rather than fundamentally addresses the problem of the obvious increase in leakage current under the action of high temperature and high electric field. Moreover, the increase in leakage current will inevitably lead to severe heating inside the capacitor, and thus causes the phenomenon of thermal runaway of capacitor. The other is to introduce two-dimension nanofillers with high insulating property, such as boron nitride nanosheets, into the polymer capacitor dielectric materials, and uses the high insulating property of nanofillers to suppress the leakage current of the composite material under the action of high temperature and high electric field. However, the problem arose from such technical method is that such ultra-thin two-dimensional nano materials must be uniformly dispersed in the polymer matrix by scheme blending, and most of high-temperature polymer dielectric materials are insoluble or even undissolved materials. Meanwhile, the compatibility between the ultra-thin two-dimensional nanofillers and most of high-temperature polymer dielectric matrix is poor and is prone to agglomeration. And thus, such ultra-thin two-dimensional nanosheets also have the problems of difficulty in preparation and high cost.

The atmospheric pressure low temperature plasma deposition technology becomes popular in the field of material surface treatment. The high-energy electrons and active particles in the low-temperature plasma may generate processes of physically etching and introducing chemical groups, etc., with the surface of the material, or complete thin film deposition on the surface of the material by introducing appropriate precursors, and thus change the physical and chemical properties of the original materials. Compared with the special requirements of traditional thin film surface deposition technology, such as magnetron sputtering, which is required to be performed in a vacuum environment, and thus is difficult to achieve large-scale continuous production; and chemical vapor deposition, which is required to be performed at high temperatures, and ordinary polymer capacitor thin films are intolerant to the temperature of during chemical vapor deposition; as well as pulsed laser deposition, which is required to be performed in a vacuum environment, and subject to the laser intensity, and thus the deposition velocity is low; the above several deposition methods generally have the disadvantages of high equipment cost and the process is complicated and difficult as well.

### SUMMARY OF THE INVENTION

The purpose of the present invention is to provide a kind of high-temperature, high-performance capacitor thin film continuous production device and method to address the aforesaid existing problems in the prior art, and thus guarantees the surface deposition of the capacitor thin film can be achieved under the conditions of atmospheric pressure and room temperature, and improves the charge and discharge efficiency and energy density of the polymer capacitor thin film under the action of high temperature and high electric field, while elevating the operating temperature of polymer capacitor thin film, and thus realizes large-scale continuous production.

For the purpose of achieving above objectives, the present invention provides following schemes:

The present invention provides a kind of high-temperature, high-performance capacitor thin film continuous production device, characterized in that consisting of an unwinding roller, an unwinding adjustment roller, a plasma deposition area, a winding adjustment roller, a drawing roller, and a winding roller which are arranged in sequence, and there are a top electrode, an upper barrier dielectric plate, a lower barrier dielectric plate, and a bottom electrode sequentially arranged in the said plasma deposition area from top to bottom, wherein the said upper barrier dielectric plate is closely attached to the said top electrode, and the said lower barrier dielectric plate is closely attached to the said bottom electrode, and there is discharge gap left between the said upper barrier dielectric plate and the lower barrier dielectric plate, in addition, there are several air inlet gaps equidistantly arranged on the said top electrode, and also several air inlet gaps equidistantly are arranged on the said upper barrier dielectric plate, furthermore, the said air inlet gaps are connected to the air inlet ducks, and the thin film to be processed released by the said unwinding roller passes through the said unwinding adjustment roller, the discharge gap, the winding adjustment roller and the drawing roller in sequence, and then is wound up by the said winding roller.

Preferably, the height direction of the said top electrode and the said upper barrier dielectric plate and/or the said lower barrier dielectric plate and the said bottom electrode is adjustable.

Preferably, the central axes of the said unwinding roller, unwinding adjustment roller, winding adjustment roller, drawing roller and winding roller are arranged in parallel.

Preferably, both the said unwinding roller and the said winding roller are inflatable rollers.

A kind of method for high-temperature, high-performance capacitor thin film continuous production, characterized in that consisting of following steps:

a: Fix the thin film to be processed on the unwinding roller, and adjust the thin film to be processed to the middle position of the discharge gap in the plasma deposition area by rotating and unwinding the unwinding roller;

b: The top electrode is connected to a high-voltage power supply, and the bottom electrode is grounded. After the power is turned on, at least one working gas and a precursor are inlet through the air inlet duct to force atmospheric pressure low-temperature plasma to be generated in the discharge gap;

c: The thin film to be processed passes through the deposition area, and the precursor undergoes certain physical and chemical changes under the action of the plasma to deposit at least one functional layer on the surface of the thin film to be processed;

d: The thin film to be processed is powered by the drawing roller after passing through the deposition area, and the processed thin film is wound by the winding roller.

Preferably, the rotate speed of the said drawing roller is adjustable, and the running speed of the thin film is adjusted by adjusting the rotate speed of the said drawing roller, and thus changes the residence time of the said thin film to be processed in the deposition area, so that changes the thickness of the deposition layer.

Preferably, the said functional layer consists of a high insulation performance layer and a high dielectric constant layer.

Preferably, the said functional layer consists of monolayer deposition or multilayer of different substances deposition.

Preferably, the said precursor consists of any one or more of tetraethyl orthosilicate, ammonia gas, silane, tantalum ethoxide, zirconium ethoxide, and hafnium ethoxide, and the said working gas consists of any one or more of helium, argon, nitrogen, air, and oxygen.

Preferably, the said high-voltage power supply is a nanosecond pulse high-voltage power supply, a microsecond pulse high-voltage power supply, a high-frequency sinusoidal high-voltage power supply, or a radio-frequency power supply.

The present invention discloses the following technical effects:

1. The present invention can realize large-scale continuous production, and can match the production speed of the existing polymer capacitor thin film, as well as can be compatible with the extrusion, stretching and manufacturing process of the existing polymer capacitor thin film, in addition, it can be flexibly configured in the current available production lines of existing polymer capacitor thin film. Furthermore, there is no need to introduce special processing techniques and special materials in the process of production.

2. The environmental requirement for operating the present invention is low, and thus can realize the deposition of the functional layer on the surface of the polymer capacitor thin film under the conditions of atmospheric pressure and room temperature.

3. The present invention can deposit different functional layers on the surface of the polymer capacitor thin film by changing different precursors to give the polymer capacitor thin film different functions, and can complete deposition treatment of various polymer capacitor thin films as well, and thus, there are no special requirements on properties of the polymer capacitor thin film.

4. The present invention can adjust the operating speed of the device through the rotate speed of the unwinding roller and the winding roller, and thus changes the thickness of the deposited layer and the processing time of the polymer capacitor thin film.

5. During the production process of the present invention, only electric energy is consumed, and the materials used are inert gases and environment friendly precursors, which will not result in environmental pollution.

### BRIEF DESCRIPTION OF THE DRAWINGS

For the purpose of explaining the embodiments of the present invention or the technical scheme in the prior art more clearly, the text below will briefly introduce the drawings that need to be used in the embodiments. Obviously, the drawings described in the following are only some of the embodiments of the present invention, and for those of ordinary skill in the art, other drawings can be obtained according to these drawings without paying any creative labor.

FIG. 1 is a schematic diagram of the present invention;

FIG. 2 is a schematic diagram of the cross section of the top electrode and the upper barrier dielectric plate of the present invention;

Wherein, consists of the unwinding roller 1, the unwinding adjustment roller 2, the thin film to be processed 3, the winding adjustment roller 4, the drawing roller 5, the winding roller 6, the processed thin film 7, the top electrode 8, the bottom electrode 9, the upper barrier dielectric plate 10, the lower barrier dielectric plate 11, the discharge gap 12, the air inlet gap 13, and the air inlet duct 14.

### DETAILED DESCRIPTION OF THE INVENTION

The technical scheme of the embodiments of the present invention will be clearly and completely described below in conjunction with the accompanying drawings of the embodiments of the present invention. Obviously, the described embodiments are only a part of the embodiments of the present invention, rather than all the embodiments. Based on the embodiments of the present invention, all other embodiments can be obtained by those of ordinary skill in the art without paying creative work shall fall within the protection scope of the present invention.

For the purpose of making the above objectives, characteristics, and advantages of the present invention simpler and more understandable, the present invention will be further described in detail below in conjunction with the accompanying drawings and specific embodiments.

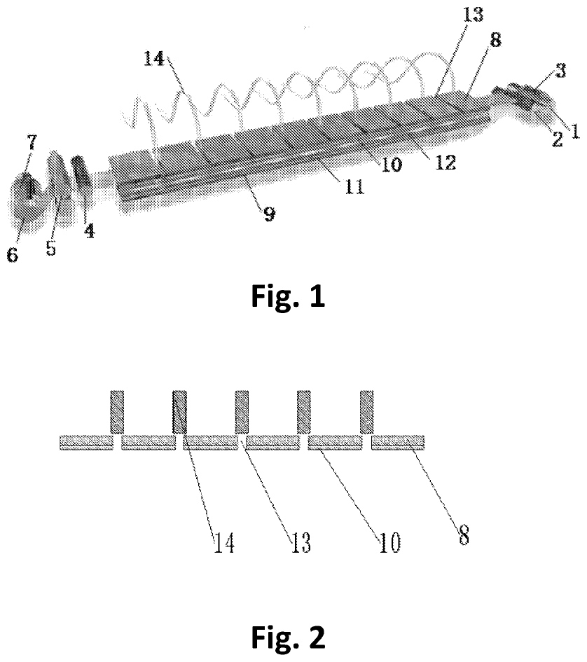

Referring to FIGS. 1-2, the present invention provides a kind of high-temperature, high-performance capacitor thin film continuous production device, which consists of an unwinding roller 1, an unwinding adjustment roller 2, a plasma deposition area, a winding adjustment roller 4, a drawing roller 5, and a winding roller 6 which are arranged in sequence, and there are a top electrode 8, an upper barrier dielectric plate 10, a lower barrier dielectric plate 11, and a bottom electrode 9 sequentially arranged in the plasma deposition area from top to bottom, wherein the upper barrier dielectric plate 10 is closely attached to the top electrode 8, and the lower barrier dielectric plate 11 is closely attached to the bottom electrode 9, and there is discharge gap 12 left between the upper barrier dielectric plate 10 and the lower barrier dielectric plate 11, in addition, there are several air inlet gaps 13 equidistantly arranged on the top electrode 8, and also several air inlet gaps 13 equidistantly are arranged on the upper barrier dielectric plate 10, furthermore, the air inlet gaps 13 are connected to the air inlet ducks 14. The unwinding roller 1 is an inflatable roller, and the position of the thin film to be processed 3 released by the unwinding roller 1 is adjusted by the unwinding adjustment roller 2, such that the thin film to be processed 3 is guaranteed to be located at the middle position of the discharge gap 12, and then the thin film to be processed 3 passes through the plasma deposition area, and the position of the processed thin film 7 is adjusted by the winding adjustment roller 4, and the processed thin film 7, after adjustment, is wound by the winding roller 6 after being drawn by the drawing roller 5, and the winding roller 6 is also an inflatable roller, which realizes the steady and controllable movement of the thin film in the deposition area.

To further optimize the scheme, the high-temperature, high-performance capacitor thin film continuous production device also comprises a frame (not shown in the figure). The top electrode 8 and the upper barrier dielectric plate 10 and/or the lower barrier dielectric plate 11 and the bottom electrode 9 achieve the adjustment of height direction through the frame, and the discharge gap is set between 0.2 mm-20 mm to guarantee uniform and stable plasma discharge to be generated in the discharge gap.

To further optimize the scheme, the central axes of the unwinding roller 1, the unwinding adjustment roller 2, the winding adjustment roller 4, the drawing roller 5 and the winding roller 6 are arranged in parallel, and the unwinding roller 1, the unwinding adjustment roller 2, the winding adjustment roller 4, the drawing roller 5 and the winding roller 6 are fixed to the frame, as well as the unwinding adjustment roller 2 and the winding adjustment roller 4 are adjusted up and down in the height direction, and thus guarantees the central axis of the thin film coincides with the central axis of the plasma deposition area, wherein, the specific structure can be embodied as an air cylinder is equipped on the frame, and one end of the air cylinder is connected to the frame, and the other end is connected to the unwinding adjustment roller 2 or the winding adjustment roller 4, and the adjustment of the height direction of the unwinding adjustment roller 2 or the winding adjustment roller 4 is driven by the telescopic movement of the air cylinder, and thus guarantees the steady continuity of production.

A kind of method for high-temperature, high-performance capacitor thin film continuous production, which consists of following steps:

a: Fix the thin film to be processed 3 on the unwinding roller 1, and adjust the thin film to be processed 3 to the middle position of the discharge gap 12 in the plasma deposition area by rotating and unwinding the unwinding roller 1;

b: The top electrode 8 is connected to a high-voltage power supply, and the bottom electrode 9 is grounded. After the power is turned on, at least one working gas and a precursor are inlet through the air inlet duct 14 to force atmospheric pressure low-temperature plasma to be generated in the discharge gap 12;

c: The thin film to be processed 3 passes through the deposition area, and the precursor undergoes certain physical and chemical changes under the action of the plasma to deposit at least one functional layer on the surface of the thin film to be processed 3;

d: The thin film to be processed 3 is powered by the drawing roller 5 after passing through the deposition area, and the processed thin film 7 is wound by the winding roller 6.

To further optimize the scheme, the rotate speed of the drawing roller 5 is adjustable, and the running speed of the thin film can be adjusted by adjusting the rotate speed of the drawing roller 5, and thus changes the residence time of the thin film to be processed 3 in the deposition area, so that changes the thickness of the deposition layer.

To further optimize the scheme, a flow meter is installed on the air inlet duct 14, and the flow rate is controlled at 0.5-20 L/min, and thus guarantees uniform and dense deposition.

To further optimize the scheme, the functional layer consists of a high insulation performance layer and a high dielectric constant layer.

To further optimize the scheme, at least one precursor and working gas can be inlet at the same time by the air inlet duct 14, and thus forms a monolayer deposition on the surface of the thin film, in addition, the intake duct 14 can also be divided into two parts at least along the production direction, which may inlet at least one different type of working gas and the precursor respectively, and thus forms multilayer of different substances deposition on the surface of the thin film.

To further optimize the scheme, the precursor consists of any one or more of ethyl orthosilicate, ammonia gas, silane, tantalum ethoxide, zirconium ethoxide, and hafnium ethoxide, and the working gas consists of any one or more of helium, argon, nitrogen, air, and oxygen, wherein, the precursor may be a gas or a liquid, and the gas can be inlet directly through the air inlet duct 14, and the liquid can be blown into the deposition area through the working gas passing through the air inlet duct 14.

Further, a high-insulating silicon dioxide layer is deposited by using the precursor of tetraethyl orthosilicate, a high-insulating silicon nitride layer is deposited by using the precursors of ammonia gas and silane, and a high dielectric constant tantalum pentoxide layer is deposited by using tantalum ethoxide, and a high-dielectric constant zirconium dioxide layer is deposited by using zirconium ethoxide, as well as a high-dielectric constant hafnium dioxide layer is deposited by using hafnium ethoxide.

To further optimize the scheme, the said high-voltage power supply is a nanosecond pulse high-voltage power supply, a microsecond pulse high-voltage power supply, a high-frequency sinusoidal high-voltage power supply, or a radio-frequency power supply. The power supply parameter adjustment takes the ability of generating uniform and stable plasma discharge as standard, and the power supply parameters consist of voltage magnitude, discharge frequency, pulse width, and pulse rising time, etc., and thus guarantee uniform and stable plasma discharge is generated in the dielectric barrier discharge gap.

To further optimize the scheme, the polymer thin film to be processed is a variety of polymer capacitor thin films currently available, including but not limited to polypropylene thin film, polyester thin film, polycarbonate thin film, polyimide thin film, polyetherimide, polyether-ether-ketone thin film, and polyphenylene sulfide thin film, etc.

The present invention realizes the large-scale continuous deposition of the functional layer on the surface of the polymer capacitor thin film, and uses the unique properties of the functional layer, such as high insulation performance and high dielectric constant performance, to improve the charge and discharge efficiency and energy storage density of the polymer capacitor thin film respectively under the action of high temperature and high electric field, and also can improve the above properties by stratified deposition. The present invention can realize large-scale continuous production, and can match the existing production speed of the polymer capacitor thin film, as well as has the advantages of flexible configuration, low environmental requirements, strong universality, fast processing speed, low production costs, and no pollution.

In the description of the present invention, it should be understood that the terms of “longitudinal”, “lateral”, “upper”, “lower”, “front”, “rear”, “left”, “right”, “vertical”, “horizontal”, “top”, “bottom”, “inner”, and “outer”, etc., which indicate the orientation or positional relationship, are based on the orientation or positional relationship shown in the drawings, and are only for the convenience of describing the present invention, rather than indicating or implying that the referred device or element must have a specific orientation, or to be configured and operated in a specific orientation, and thus cannot be understood as a limitation of the present invention.

The above-mentioned embodiments only describe the preferred modes of the present invention, rather than limit the scope of the present invention. In the premise of not departing from the design spirit of the present invention, any variation and improvement of the technical scheme of the present invention made by those of ordinary skill in the art shall fall within the protection scope determined by the claims of the present invention.

1. A kind of high-temperature, high-performance capacitor thin film continuous production device, characterized in that consisting of an unwinding roller (1), an unwinding adjustment roller (2), a plasma deposition area, a winding adjustment roller (4), a drawing roller (5), and a winding roller (6) which are arranged in sequence, and there are a top electrode (8), an upper barrier dielectric plate (10), a lower barrier dielectric plate (11), and a bottom electrode (9) sequentially arranged in the said plasma deposition area from top to bottom, wherein the said upper barrier dielectric plate (10) is closely attached to the said top electrode (8), and the said lower barrier dielectric plate (11) is closely attached to the said bottom electrode (9), and there is discharge gap (12) left between the said upper barrier dielectric plate (10) and the lower barrier dielectric plate 11, in addition, there are several air inlet gaps 13 equidistantly arranged on the said top electrode (8), and also several air inlet gaps 13 equidistantly are arranged on the said upper barrier dielectric plate (10), furthermore, the said air inlet gaps 13 are connected to the air inlet ducks 14. In addition, the thin film to be processed (3) released by the said unwinding roller (1) is wound by the said winding roller (6) after passing through the said unwinding adjustment roller (2), the discharge gap (12), the winding adjustment roller (4) and the drawing roller (5) in sequence.

2. The kind of high-temperature, high-performance capacitor thin film continuous production device according to claim 1, characterized in that: the height direction of the said top electrode (8) and the said upper barrier dielectric plate (10) and/or the said lower barrier dielectric plate (11) and of the said bottom electrode (9) can be adjusted up and down.

3. The kind of high-temperature, high-performance capacitor thin film continuous production device according to claim 1, characterized in that: the central axes of the said unwinding roller (1), the unwinding adjustment roller (2), the winding adjustment roller (4), the drawing roller (5) and the winding roller (6) are arranged in parallel.

4. The kind of high-temperature, high-performance capacitor thin film continuous production device according to claim 1, characterized in that: both said unwinding roller (1) and the said winding-up roller (6) are inflatable rollers.

5. A kind of method for high-temperature, high-performance capacitor thin film continuous production, which consists of following steps:
a: Fix the thin film to be processed (3) on the unwinding roller (1), and adjust the thin film to be processed (3) to the middle position of the discharge gap (12) in the plasma deposition area by rotating and unwinding the unwinding roller (1);
b: The top electrode (8) is connected to a high-voltage power supply, and the bottom electrode (9) is grounded. After the power is turned on, at least one working gas and a precursor are inlet through the air inlet duct (14) to force atmospheric pressure low-temperature plasma to be generated in the discharge gap (12);
c: The thin film to be processed (3) passes through the deposition area, and the precursor undergoes certain physical and chemical changes under the action of the plasma to deposit at least one functional layer on the surface of the thin film to be processed (3);
d: The thin film to be processed (3) is powered by the drawing roller (5) after passing through the deposition area, and the processed thin film (7) is wound by the winding roller (6).

6. The kind of method for high-temperature, high-performance capacitor thin film continuous production according to claim 5, characterized in that: the rotate speed of the said drawing roller (5) is adjustable, and the running speed of the thin film can be adjusted by adjusting the rotate speed of the said drawing roller (5), and thus changes the residence time of the said thin film to be processed (3) in the deposition area, so that changes the thickness of the deposition layer.

7. The kind of method for high-temperature, high-performance capacitor thin film continuous production according to claim 5, characterized in that: the said functional layer consists of a high insulation performance layer and a high dielectric constant layer.

8. The kind of method for high-temperature, high-performance capacitor thin film continuous production according to claim 5, characterized in that: the said functional layer consists of monolayer deposition or multilayer of different substances deposition.

9. The kind of method for high-temperature, high-performance capacitor thin film continuous production according to claim 5, characterized in that: the said precursor consists of any one or more of tetraethyl orthosilicate, ammonia gas, silane, tantalum ethoxide, zirconium ethoxide, and hafnium ethoxide, and the said working gas consists of any one or more of helium, argon, nitrogen, air, and oxygen.

10. The kind of method for high-temperature, high-performance capacitor thin film continuous production according to claim 5, characterized in that: the said high-voltage power supply is a nanosecond pulse high-voltage power supply, a microsecond pulse high-voltage power supply, a high-frequency sinusoidal high-voltage power supply, or a radio-frequency power supply.
